(19) United States
(12) Patent Application Publication
(10) Pub. No.: US 2024/0389329 A1
(43) Pub. Date: Nov. 21, 2024

(54) MEMORY DEVICE HAVING MEMORY CELL STRINGS AND SHARED READ AND WRITE CONTROL GATES

(71) Applicant: Micron Technology, Inc., Boise, ID (US)

(72) Inventors: Albert Fayrushin, Boise, ID (US); Haitao Liu, Boise, ID (US); Kamal M. Karda, Boise, ID (US)

(21) Appl. No.: 18/666,358

(22) Filed: May 16, 2024

Related U.S. Application Data
(60) Provisional application No. 63/467,804, filed on May 19, 2023.

(51) Int. Cl. H10B 43/35; H10B 41/27; H10B 41/35; H10B 43/27

(52) U.S. Cl. CPC H10B 43/35; H10B 41/27; H10B 41/35; H10B 43/27

(57) ABSTRACT

Some embodiments include apparatuses and methods of operating the apparatuses. One of the apparatuses includes a memory device, which includes a first memory cell string, a second memory cell string adjacent the first memory cell string, and a control gate. The first memory string includes a first channel structure, a first charge storage structure, and a first dielectric structure between the first channel structure and the first charge storage structure. The second memory cell string includes a second channel structure, a second charge storage structure, and a second dielectric structure between the second channel structure and the second charge storage structure. The control gate is separated from the first charge storage structure by a third dielectric structure and separated from the second channel structure by a fourth dielectric structure. The control gate and the first charge storage structure are between the first channel structure and the second channel structure.

### PRIORITY APPLICATION

This application claims the benefit of priority to U.S. Provisional Application Ser. No. 63/467,804, filed May 19, 2023, which is incorporated herein by reference in its entirety.

### TECHNICAL FIELD

Embodiments described herein relate to memory devices including memory cell strings and control gates associated with the memory cell strings.

### BACKGROUND

Memory devices, such as flash memory devices, are widely used in computers and many other electronic items. A memory device usually has numerous memory cells that have charge storage structures for storing information (e.g., data) and data lines for carrying information (in the form of electrical signals) to and from the memory cells. The memory device also has control gates for accessing the memory cells during a write operation to store information in the memory cells or during a read operation to read information (e.g., previously stored information) from the memory device. Some conventional memory devices are structured such that separate control gates are used for read and write operations in the same memory cells of the memory device. The structure of such conventional memory devices can lead to lower memory cell density and difficulty in scaling ability.

### BRIEF DESCRIPTION OF THE DRAWINGS

FIG. 1 is a block diagram of an apparatus in the form of a memory device, according to some embodiments described herein.

FIG. 2A and FIG. 2B show schematic diagrams of a portion of a memory device, according to some embodiments described herein.

FIG. 3A shows a structure of a portion of the memory device of FIG. 2A and FIG. 2B, according to some embodiments described herein.

FIG. 3B and FIG. 3C show alternative structures of the memory device of FIG. 3A, according to some embodiments described herein.

FIG. 4 shows an example read operation of the memory device of FIG. 3A including example voltages applied to different portions of the memory device, according to some embodiments described herein.

FIG. 5 shows an example write operation of the memory device of FIG. 3A including example voltages applied to different portions of the memory device, according to some embodiments described herein.

FIG. 6A and FIG. 6B show example erase operations of the memory device of FIG. 3A including example voltages applied to different portions of the memory device, according to some embodiments described herein.

FIG. 7A and FIG. 7B show schematic diagrams of a portion of a memory device that can be a variation of the memory device of FIG. 2A and FIG. 2B, according to some embodiments described herein.

FIG. 8A shows a structure of a portion of the memory device of FIG. 7A and FIG. 7B, according to some embodiments described herein.

FIG. 8B and FIG. 8C show alternative structures of the memory device of FIG. 3A, according to some embodiments described herein.

FIG. 9 shows an example read operation of the memory device of FIG. 8A including example voltages applied to different portions of the memory device, according to some embodiments described herein.

FIG. 10 shows an example write operation of the memory device of FIG. 8A including example voltages applied to different portions of the memory device, according to some embodiments described herein.

FIG. 11 shows an example erase operation of the memory device of FIG. 8A including example voltages applied to different portions of the memory device, according to some embodiments described herein.

FIG. 12A and FIG. 12B show additional example erase operations of the memory device of FIG. 8A including example voltages applied to different portions of the memory device, according to some embodiments described herein.

### DETAILED DESCRIPTION

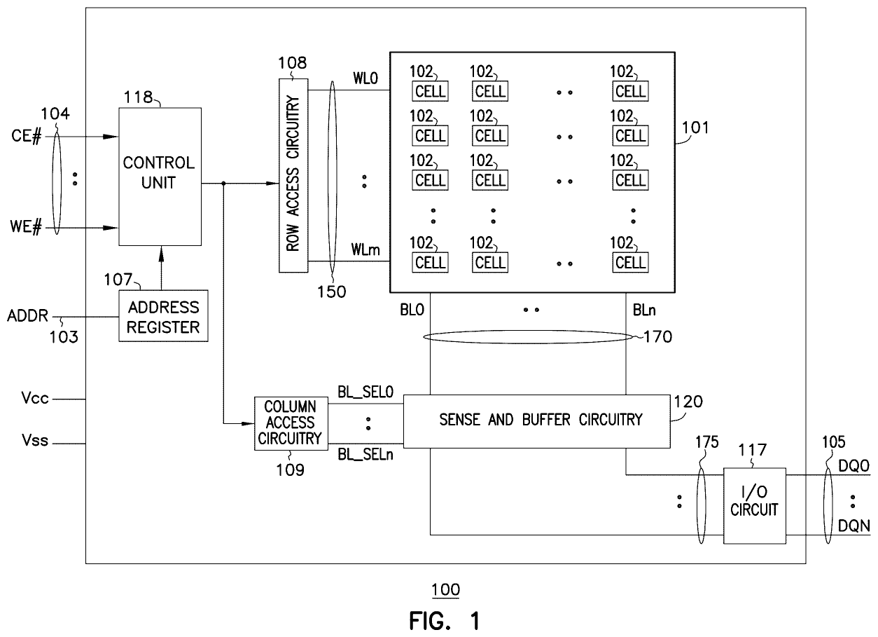

The techniques described herein provide a memory device having a structure that allows sharing of control gates (e.g., word lines). The described memory device includes control gates that can be shared by different memory cells in different operations (e.g., read and write operations). In an example, the describe memory device includes a control gate that can be used to select a memory cell in a read operation and to select another memory cell (e.g., an adjacent memory cell) in a write operation. The structure of the memory device described herein can reduce or prevent read disturbance that may occur in some conventional memory devices. Moreover, the size (e.g., footprint) of the device structure described herein can be relatively small. This can be beneficial for device scaling. Improvements and benefits of the techniques described herein are further discussed below with reference to FIG. 1 through FIG. 12B.

FIG. 1 shows a block diagram of an apparatus in the form of a memory device, according to some embodiments described herein. Memory device 100 can include a memory array (or multiple memory arrays) 101 containing memory cells 102. Memory cells 102 can be arranged in memory cell strings where each memory cell string can include multiple memory cells connected in series with each other.

As shown in FIG. 1, memory device 100 can include access lines (which can include word lines) 150 and data lines (which can include bit lines) 170. Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 and data lines 170 to selectively exchange information (e.g., data) with memory cells 102.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 are to be accessed during a memory operation. Memory device 100 can perform a read operation to read (e.g., sense) information (e.g., previously stored information) from memory cells 102, or a write (e.g., programming) operation to store (e.g., program) information in memory cells 102. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102.

Memory device 100 can include a control unit 118 that can be configured to control memory operations of memory device 100 based on control signals on lines 104. Examples of the control signals on lines 104 include one or more clock signals and other signals (e.g., a chip enable signal CE #, a write enable signal WE #) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that causes memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) and provide the value of the information to lines (e.g., global data lines) 175. Sense and buffer circuitry 120 can also be configured to use signals on lines 175 to determine the value of information to be stored (e.g., programmed) in memory cells 102 (e.g., during a write operation) based on the values (e.g., voltage values) of signals on lines 175 (e.g., during a write operation).

Memory device 100 can include input/output (I/O) circuitry 117 to exchange information between memory cells 102 and lines (e.g., I/O lines) 105. Signals DQ0 through DQN on lines 105 can represent information read from or stored in memory cells 102. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105. Thus, memory device 100 can be coupled to an external device (or devices) to perform memory operation (e.g., read, write, and erase operations) responsive to commands from the external device (or devices).

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits (e.g., more than three bits in each memory cell). A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., three-dimensional (3D) NAND) or a NOR flash memory device, or another kind of memory device, such as a variable resistance memory device (e.g., a phase change memory device or a resistive Random Access Memory (RAM) device).

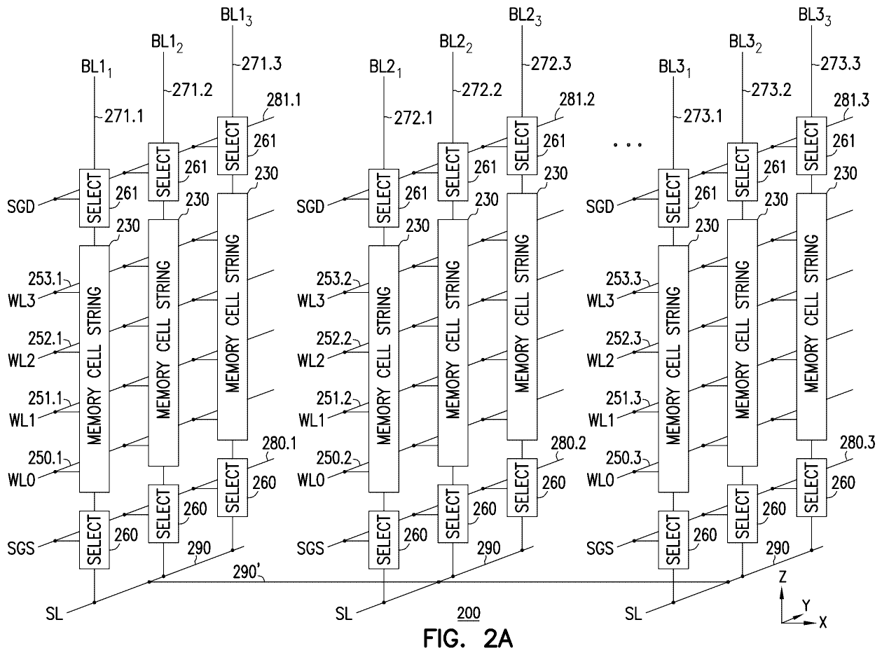

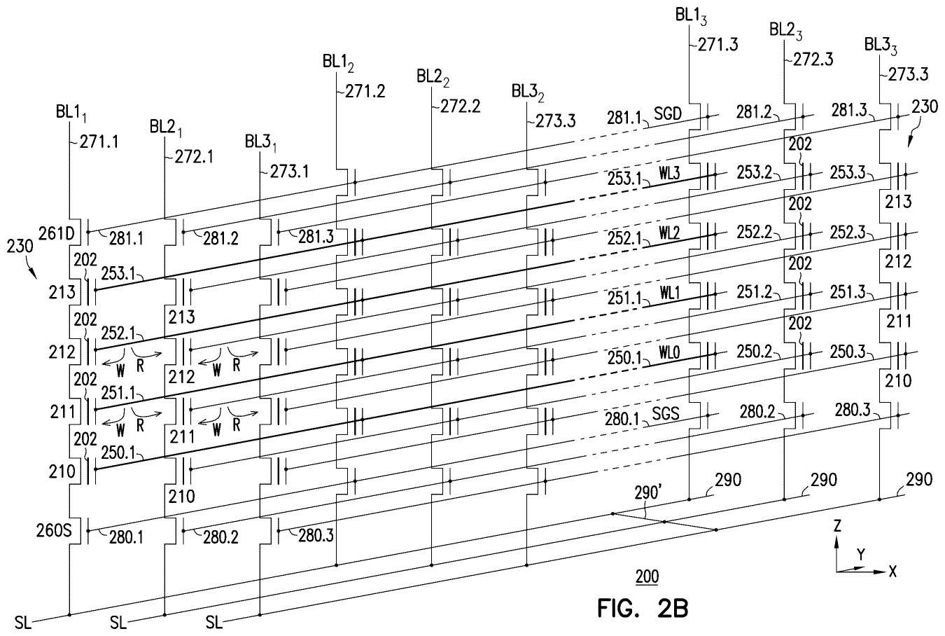

One of ordinary skill in the art may recognize that memory device 100 may include other components, several of which are not shown in FIG. 1 so as not to obscure the example embodiments described herein. At least a portion of memory device 100 can include structures and perform operations similar to or the same as the structures and operations of any of the memory devices described below with reference to FIG. 2A through FIG. 12B.

FIG. 2A and FIG. 2B show schematic diagrams of a portion of a memory device 200. FIG. 2B shows details of memory device 200 of FIG. 2A. As shown in FIG. 2A, memory device 200 can include memory cell strings 230 and control gates (e.g., part of word lines) associated with memory cell strings 230. Memory device 200 can correspond to memory device 100 of FIG. 1. For example, memory cell strings 230 can form part of memory array 101 of FIG. 1. As shown in FIG. 2A, memory device 200 can also include select circuits (labeled “SELECT”) 260 and 261, data lines 271.1, 271.2, and 271.3; data lines 272.1, 272.2, and 272.3; and data lines 273.1, 273.2, and 273.3; and sources 290.

FIG. 2A shows specific number (quantity) of circuit elements (e.g., control gates, data lines, and memory cell strings 230) of memory device 200 as an example. However, the number of the circuit elements of memory device 200 can be different from the numbers shown in FIG. 2A.

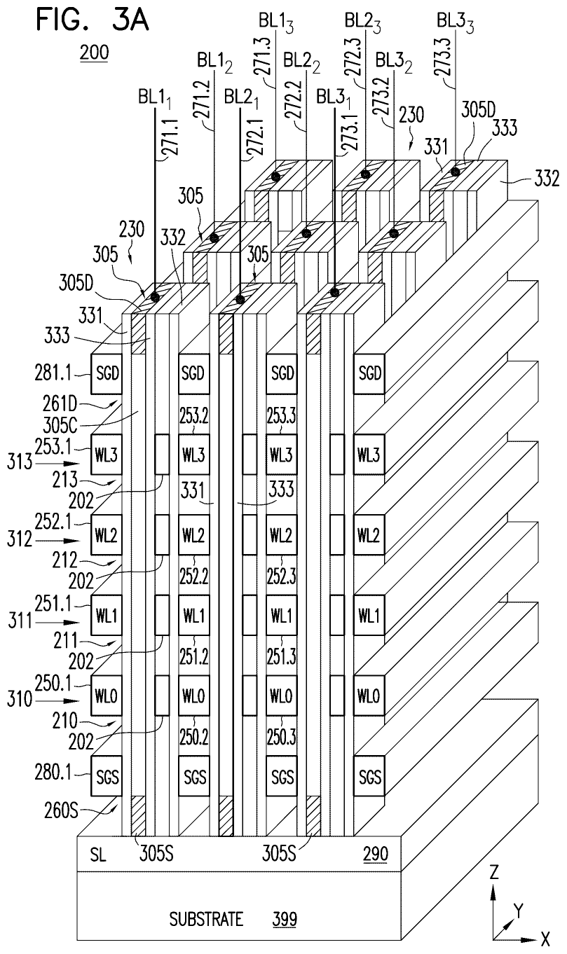

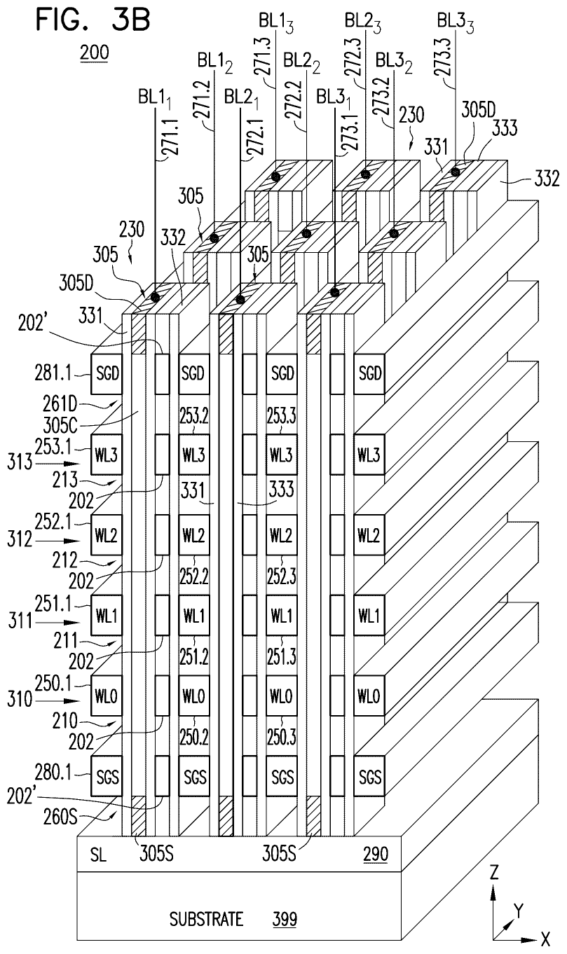

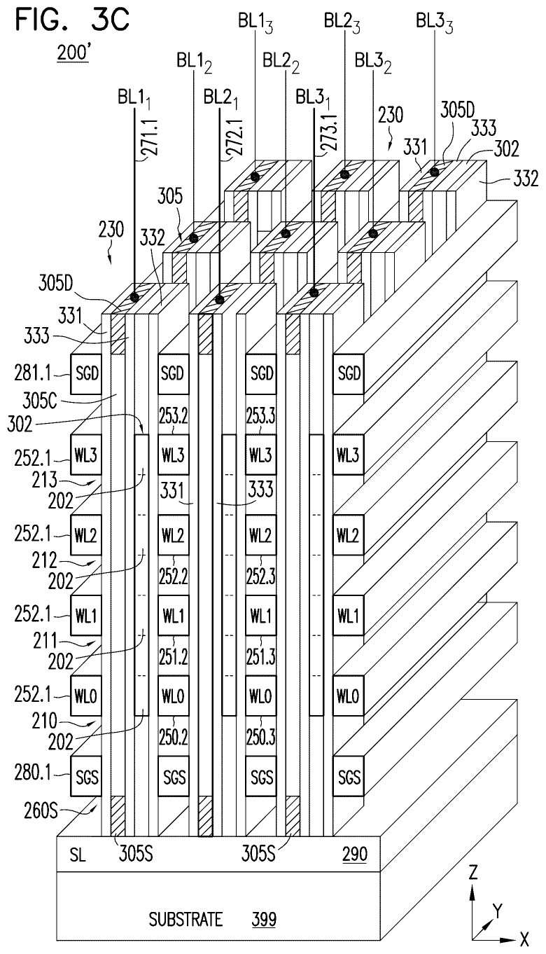

In FIG. 2A and FIG. 2B, directions X, Y, and Z can represent relative physical directions (e.g., dimensions) of the structure of memory device 200. For example, the Z-direction can be a direction perpendicular to (e.g., vertical direction with respect to) a plane (e.g., X-Y plan) of substrate (e.g., a substrate 399 shown in FIG. 3A) of memory device 200.

As shown in FIG. 2A, the control gates can be divided into different groups of control gates that can be electrically separated from each other. For example, FIG. 2A shows an example of three groups of control that include a group of control gates 250.1, 251.1, 252.1, and 253.1, a group of control gates 250.2, 251.2, 252.2, and 253.2, and a group of control gates 250.3, 251.3, 252.3, and 253.3.

The control gates within the same group are electrically separated from each other. The control gates from one group can be electrically separated from the control gates of another group. The control gates can be provided with (e.g., associated with) respective signals (e.g., word line signals) WL0, WL1, WL2, and WL3.

Signals WL0, WL1, WL2, and WL3 associated with one group of control gates can be different from signals WL0, WL1, WL2, and WL3 associated with another group of control gates. However, for simplicity, FIG. 2A shows the same labels for signals WL0, WL1, WL2, and WL3 in different groups of the control gates.

The number of control gates are the same in the group of control gates. FIG. 2A shows an example of four control gates (e.g., control gates 250.1, 251.1, 252.1, and 253.1) and four associated signals (e.g., signals WL0, WL1, WL2, and WL3) in a control gate group. However, the number of control gates in each group of control gates can be different from four. For simplicity, control gates 250.1, 251.1, 252.1, and 253.1; 250.2, 251.2, 252.2, and 253.2; and 250.3, 251.3, 252.3, and 253.3 shown in FIG. 2A and FIG. 2B and other similar control gates (not shown) of memory device 200 are sometimes called “the control gates” without accompanying numeric labels.

The control gates of memory device 200 can be part of conductive lines that can include conductive materials. Examples of such conductive materials include conductively doped polycrystalline silicon (doped polysilicon), metals, or other conductive materials.

As shown in FIG. 2A, each group of control gates can be associated with (e.g., coupled to) a particular group of memory cell strings 230.

For example, control gates 250.1, 251.1, 252.1, and 253.1 can be associated with memory cell strings 230 that are associate with (e.g., coupled to) data lines 271.1, 271.2, and 271.3. Control gates 250.1, 251.2, 252.3, 253.2 can be associated with memory cell strings 230 that are associate with (e.g., coupled to) data lines 272.1, 272.2, and 272.3. Control gates 250.3, 251.3, 252.3, and 253.3 can be associated with memory cell strings 230 that are associate with (e.g., coupled to) data lines 273.1, 273.2, and 273.3.

A particular group of control gates can be used to control access (e.g., during a read or write operation) to memory cells of memory cell strings 230 associated with (e.g., coupled to) that particular group of control gates. FIG. 2A shows memory device 200 having nine memory cell strings 230 and associated control gates and select circuits 260 and 261 as an example. However, memory device 200 can have numerous memory cell strings 230 and associated control gates and select circuits 260 and 261.

As shown in FIG. 2A, each memory cell string 230 can be associated with (e.g., coupled to) a respective select circuit 260 and a respective select circuit 261. Select circuits 261 and 260 can correspond to drain select gate (SGD) and source select gate (SGS) circuits, respectively, of a memory device such as a NAND flash memory device. Each memory cell string 230 can include memory cells (e.g., memory cells 210, 211, 212, and 213 in FIG. 2B) connected in series between a respective select circuit 260 and a respective select circuit 261 (or between a respective data line and source 290, as shown in FIG. 2A and FIG. 2B).

As shown in FIG. 2A, memory device 200 can include select lines (e.g., drain select lines) 281.1, 281.2, and 281.3 associated with signals (e.g., select signals) SGD. Signals SGD can be different from each other. However, for simplicity, FIG. 2A shows the same label for signal SGD in different select lines (e.g., select lines 281.1, 281.2, and 281.3).

Select lines 281.1, 281.2, and 281.3 can be electrically separated from each other. Thus, signals SGD can be activated (or deactivated) separately (e.g., independently). For example, signal SGD associated with select line 281.1 can be activated or deactivated separately (e.g., independently) from signal SGD associated with select line 281.2 or select line 281.3.

As shown in FIG. 2A, select line 281.1 can be coupled to (e.g., can be shared by) select circuits 261 associated with memory cell strings that are associated with the same control gates 250.1, 251.1, 252.1, and 253.1. Similarly, select line 281.2 can be coupled to (e.g., can be shared by) select circuits 261 associated with memory cell strings that are associated with the same control gates 250.2, 251.2, 252.2, and 253.2. Select line 281.3 can be coupled to (e.g., can be shared by) select circuits 261 associated with memory cell strings that are associated with the same control gates 250.3, 251.3, 252.3, and 253.3. As described below, signals SGD associated with select lines 281.1, 281.2, and 281.3 can be activated to couple respective memory cell strings 230 to respective data lines (through select circuits 261) or can be deactivated to decouple respective memory cell strings 230 from respective data lines.

As shown in FIG. 2A, memory device 200 can include select lines (e.g., source select lines) 280.1, 280.2, and 280.3 associated with signals (e.g., select signals) SGS. Thus, signals SGS can be different from each other. However, for simplicity, FIG. 2A shows the same label for signal SGS in different select lines (e.g., select lines 280.1, 280.2, and 280.3).

Select lines 280.1, 280.2, and 280.3 can be electrically separated from each other. Thus, signals SGS can be activated (or deactivated) separately (e.g., independently). For example, signal SGS associated with select line 280.1 can be activated or deactivated separately (e.g., independently) from signal SGS associated with select line 280.2 or select line 280.3.

In an alternative structure memory device 200, two or more of select lines 280.1, 280.2, and 280.3 can be electrically coupled to each other.

As shown in FIG. 2A, select line 280.1 can be coupled to (e.g., can be shared by) select circuits 260 associated with memory cell strings that are associated with the same control gates 250.1, 251.1, 252.1, and 253.1. Similarly, select line 280.2 can be coupled to (e.g., can be shared by) select circuits 260 associated with memory cell strings that are associated with same control gates 250.2, 251.2, 252.2, and 253.2. Select line 280.3 can be coupled to (e.g., can be shared by) select circuits 260 associated with memory cell strings that are associated with the same control gates 250.3, 251.3, 252.3, and 253.3. As described below, signals SGS associated with select lines 280.1, 280.2, and 280.3 can be activated to couple respective memory cell strings 230 to respective sources 290 or can be deactivated to decouple respective memory cell strings 230 from sources 290.

Memory device 200 can selectively activate (e.g., selectively turn on or turn off) select circuits 260 and 261 during a memory operation (e.g., read write operation) of memory device 200 using corresponding select lines coupled to select circuits 260 and 261. Memory device 200 can activate one or both of select circuit 260 and 261 associated with a selected memory cell string 230, depending on which memory operation (e.g., read or write operation) that memory device 200 performs on the selected memory cell strings 230. A selected memory cell string is the memory cell string (among memory cell strings 230) that memory device 200 selects to store information in or read information from a memory cell (e.g., one of memory cells 210, 211, 212, and 213 in FIG. 2B) of that memory cell string. Selected memory cell strings can also include memory cell strings that are selected to be erased in an erase operation.

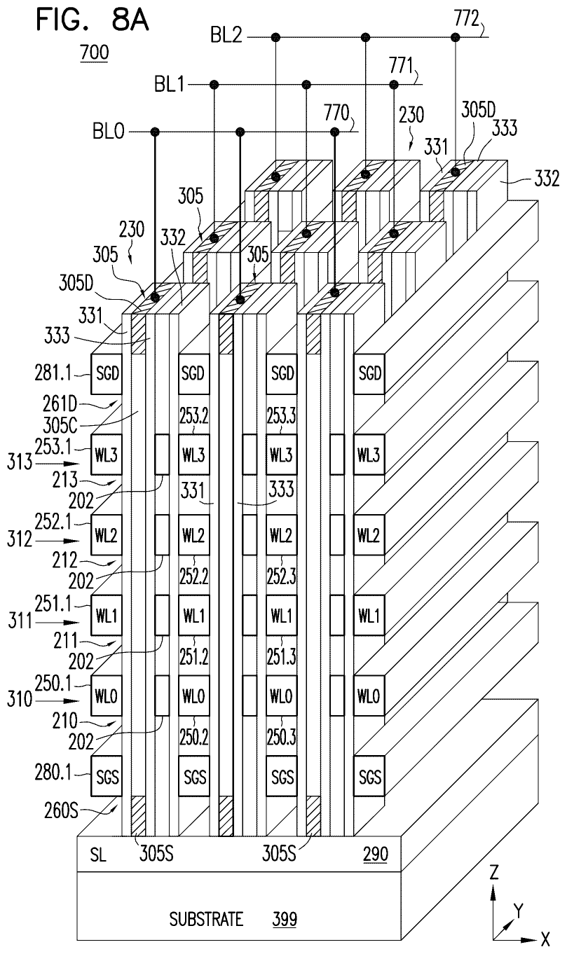

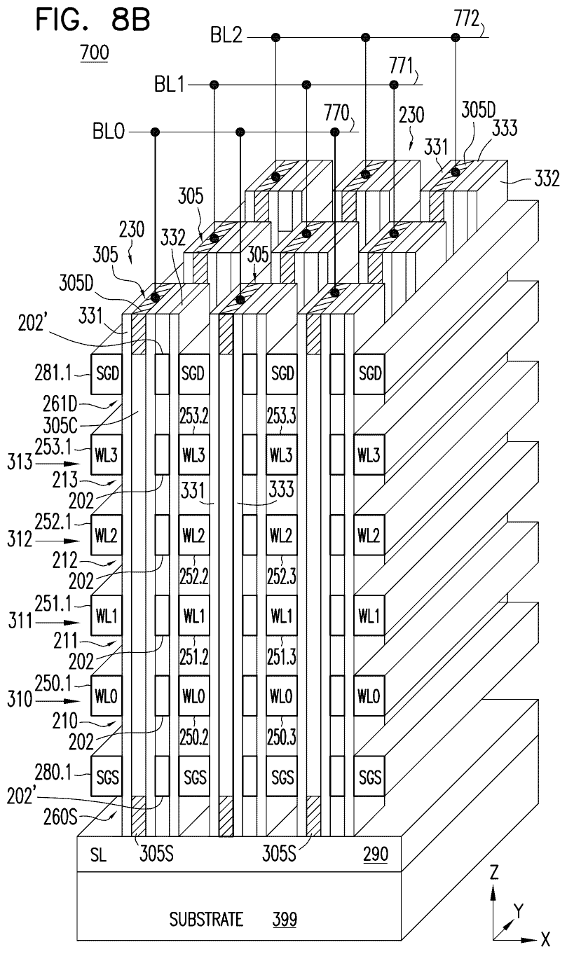

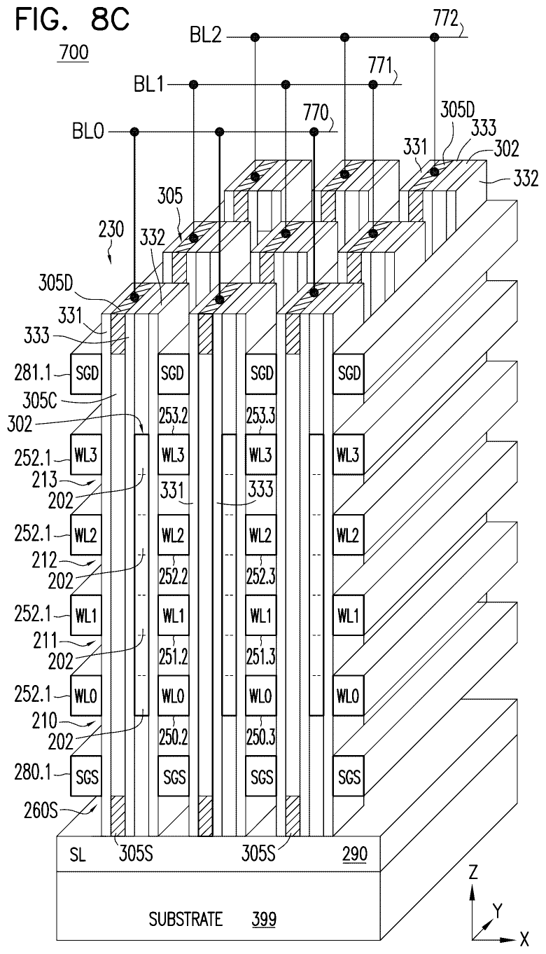

In FIG. 2A, data lines 271.1, 271.2, and 271.3, data lines 272.1, 272.2, and data lines 272.3, 273.1, 273.2, and 273.3 can be structured as conductive lines that can include conductive materials. Examples of such conductive materials include conductively doped polycrystalline silicon (doped polysilicon), metals, or other conductive materials. FIG. 2A shows an example where data lines 271.1, 271.2, and 271.3, 272.1, 272.2, and 272.3, 273.1, 273.2, and 273.3 are electrically separated from each other. In an alternative structure of memory device 200 (e.g., as shown in FIG. 8A), multiple data lines can be electrically coupled to each other (e.g., shared data lines among memory cell strings).

As shown in FIG. 2A, each source 290 can be associated with respective memory cell strings 230. Each Source 290 can be used to carry a signal (e.g., a source line signal) SL. Each source 290 can be structured as a conductive line (e.g., a source line) or a conductive plate (e.g., conductive region). FIG. 2A shows sources 290 can be coupled to each other through a conductive connection 290′. Thus, sources 290 can be formed from a common conductive structure (e.g., a common conductive plate) of memory device 200. In an alternative structure of memory device 200, conductive connection 290′ can be omitted.

FIG. 2B shows details of memory device 200 of FIG. 2A. As shown in FIG. 2B, select circuit 261 can include a select transistor (e.g., drain select transistor) 261D. Select transistor 261D can be controlled (e.g., turned on or turned off) by a respective select line (e.g., select line 281.1, 281.2, or 281.3). For example, select transistor 261D of select circuit 261 coupled to select line 281.1 can be turned on when signal SGD associated with select line 281.1 is activated (e.g., provided with a positive voltage) or turned off when signal SGD associated with select line 281.1 is deactivated (e.g., provided with ground (GND) potential).

As shown in FIG. 2B, select circuit 260 can include a select transistor (e.g., source select transistor) 260S. Select transistor 260S can be controlled (e.g., turn on or turned off) by a respective select line (e.g., select line 280.1, 280.2, or 280.3). For example, select transistor 260S in FIG. 2B) of select circuit 260 coupled to select line 280.1 can be turned on when signal SGS associated with select line 280.1 is activated (e.g., provided with a positive voltage) or turned off when signal SGS associated with select line 280.1 is deactivated (e.g., provided with ground (GND) potential).

As shown in FIG. 2B, memory cells 210, 211, 212, and 213 of each memory cell string 230 can be coupled in series with each other between respective select transistors 260S and 261D. Each of memory cells 210, 211, 212, and 213 can include a charge storage structure 202. Charge storage structure 202 can form the memory element of a respective memory cell (among memory cells 210, 211, 212, and 213) of memory cell string 230. Charge storage structure 202 can include a material (or materials) that can be structured to store charge (e.g., can trap charge). Example materials for charge storage structure 202 includes a dielectric material (e.g., silicon nitride). Another example material for charge storage structure 202 includes polysilicon. Another example material for charge storage structure 202 includes metal.

The value (e.g., digital value) of information stored in a particular memory cell (among memory cells 210, 211, 212, and 213) can be based on the amount of charge in charge storage structure 202 of that particular memory cell. Charge storage structure 202 can be configured such that each memory cell (e.g., each of memory cells 210, 211, 212, and 213) can be configured to store a single bit or multiple bits of information.

As shown in FIG. 2B, each of memory cells 210, 211, 212, and 213 can be associated with (e.g., can be coupled to) a respective control gate. For example, in memory cell string 230 coupled to data line 271.1, memory cells 210, 211, 212, and 213 can be associated with control gate 250.1, 251.1, 252.1, and 253.1, respectively. In another example, in memory cell string 230 coupled to data line 272.1, memory cells 210, 211, 212, and 213 (not labeled) can be associated with control gate 250.2, 251.2, 252.2, and 253.2, respectively. In another example, in memory cell string 230 coupled to data line 273.1, memory cells 210, 211, 212, and 213 (not labeled) can be associated with control gate 250.3, 251.3, 252.3, and 253.3, respectively.

Memory device 200 can use one control gate for reading information from a selected memory cell (in a read operation) and another control gate for storing (writing) information in the selected memory cell (in a write operation). Thus, in memory device 200, two different control gates (e.g., two different word lines) can be used for two different operations (e.g., read and write operations) performed (at different times) on the same selected memory cell.

In FIG. 2B, label “W” and “R” near a control gate indicate that the same control gate can be used to select a memory cell in a write operation (to store information in the selected memory cell in the write operation) and to select another memory cell (at a different time) in a read operation (to read information from the selected memory cell in the read operation). Thus, in memory device 200, one control gate can be shared by two different memory cells (e.g., adjacent memory cells) for different memory operations (e.g., read and write operations) at different times. For example, control gate 252.1 can be used to select memory cell 212 of memory cell string 230 coupled to data line 271.1 (associated with signal BL1₁) during a write operation to store information in it (in memory cell 212 of memory cell string 230 coupled to data line 271.1). Control gate 252.1 can also be used to select memory cell 212 of memory cell string 230 coupled to data line 272.1 (associated with signal BL2₁) during a read operation to read information from it (from memory cell 212 memory cell 212 of memory cell string 230 coupled to data line 272.1).

In another example, control gate 252.2 can be used to select memory cell 212 of memory cell string 230 coupled to data line 272.1 (associated with signal BL2₁) during a write operation to store information in it (in memory cell 212 of memory cell string 230 coupled to data line 272.1). Control gate 252.2 can also be used to select memory cell 212 of memory cell string 230 coupled to data line 273.1 (associated with signal BL3₁) during a read operation to read information from it (from memory cell 212 of memory cell string 230 coupled to data line 273.1).

Thus, each memory cell of a memory cell string can be associated with two different control gates: one control gate for reading information from the memory cell in a read operation and another control gate for writing information in the memory cell in a write operation. In an operation (e.g., read or write operation) of a memory device, one of the two control gates associated with a memory cell can be activated (e.g., provided with a positive voltage) and the other control gate can be deactivated (e.g., grounded) or, alternatively, placed in a float condition. Placing a particular circuit element (e.g., a control line, a data line, or a select line) in a float condition includes not coupling that particular circuit element (e.g., a control line, a data line, or a select line) to a fixed voltage, such that a voltage on that circuit element may change (e.g., increase or decrease) during an operation (e.g., read, write, or erase operation). Example voltages applied to the control gates, the data lines, and the select lines of memory device 200 in a memory operation (e.g., read, write, or erase operation) are further described below with reference to FIG. 3A through FIG. 6B.

FIG. 3A shows of a structure of a portion of memory device 200 of FIG. 2A and FIG. 2B, according to some embodiments described herein. Some of the elements of the structure of the portion of memory device 200 shown in FIG. 3A are schematically shown in FIG. 2A and FIG. 2B. For simplicity, the same elements of memory device 200 shown in FIG. 2A, FIG. 2B, and FIG. 3A are given the same labels. Details of the same elements are not repeated. For simplicity and to avoid crowding FIG. 3A, only some of the elements of memory device 200 are labeled. The similar or the same elements of memory device 200 in FIG. 3A are not labeled.

For simplicity, cross-sectional lines (e.g., hatch lines) are omitted from most of the elements shown in FIG. 3A and other figures in the drawings described herein. Some elements of memory device 200 (and other memory devices described herein) may be omitted from a particular figure of the drawings so as to not obscure the description of the element (or elements) being described in that particular figure. The dimensions (e.g., physical structures) of the elements shown in the drawings described herein are not scaled.

FIG. 3A shows a 3D view (e.g., isometric views) in the X, Y, and Z directions of memory device 200 including nine memory cell strings 230 having respective memory cells 210, 211, 212, and 213. For simplicity and to avoid crowding FIG. 3A, memory cells 210, 211, 212, and 213 of only one memory cell string 230 are labeled in FIG. 3A.

As shown in FIG. 3A, memory cell strings 230 can be formed over source 290, which is formed over (e.g., formed on or formed in) a substrate 399. Source 290 can include a conductive region, which can include a conductive material or a combination of conductive materials (e.g., different levels (e.g., layers) of conductive materials). Example materials for source 290 include conductively doped polysilicon, metal, or a combination of these materials or other conductive materials.

Substrate 399 of memory device 200 can include monocrystalline (also referred to as single-crystal) semiconductor material. For example, substrate 399 can include monocrystalline silicon (also referred to as single-crystal silicon). The monocrystalline semiconductor material of substrate 399 can include impurities, such that substrate 399 can have a specific conductivity type (e.g., n-type or p-type).

As shown in FIG. 3A, memory cell strings 230 can include respective channel structures 305. Channel structures 305 can be electrically coupled to respective data lines 271.1, 271.2, 271.3, 272.1, 272.2, 272.3, 273.1, 273.2, and 273.3 during a memory operation of memory device 200. Channel structures 305 can also be electrically coupled to source (e.g., a conductive region) 290 during a memory operation of memory device 200.

As shown in FIG. 3A, channel structure 305 of a respective memory cell string 230 can include a portion (e.g., channel portion) 305C, a portion (e.g., drain portion) 305D coupled to portion 305C, and a portion (e.g., source portion) 305S coupled to portion 305C, such that portion 305C is between portions 305D and 305S. Channel structure 305 can include a material (e.g., a conductive material) that can conduct a current. Example materials for channel structure 305 include polysilicon (e.g., doped or undoped polysilicon). Channel structure 305 can operate to conduct current to a respective memory cell string 230. In a memory operation (e.g., read operation), each channel structure 305 can conduct a current (e.g., electrons) between source 290 and a respective data line (e.g., among data lines 271.1, 271.2, 271.3, 272.1, 272.2, 272.3, 273.1, 273.2, and 273.3).

Portions 305C, 305D, and 305S can include conductively doped polycrystalline silicon (conductively doped polysilicon). Portions 305C, 305D, and 305S can have the same type of dopants. For example, portions 305C, 305D, and 305S can have N-type dopants (or alternatively P-type dopants).

Portions 305C, 305D, and 305S can have different doping concentrations. In an example, each of portions 305D and 305S can have a higher doping concentration than portion 305C. For example, each of portions 305D and 305S can be heavily doped with N-type dopant (e.g., N+ (N plus)) type), and portion 305C can be lightly doped with N-type dopant (e.g., N− (N minus) type). Alternatively, each of portions 305D and 305S can be heavily doped with P-type dopant (e.g., P+ (P plus)) type), and portion 305C can be lightly doped with P-type dopant (e.g., P− (P minus) type).

Portions 305S and source 290 can have the same material. Portions 305S and source 290 can have the same doping concentration. For example, portions 305S and source 290 can have N-type dopants (e.g., N+ type) or, alternatively, P-type dopants (e.g., P+ type).

As shown in FIG. 3A, memory device 200 can also include dielectric structures (e.g., gate oxides) 331, dielectric structures (e.g., tunneling oxides) 332, and dielectric structures (e.g., blocking oxides) 333. Dielectric structure 331 can be between channel structure 305 of a respective memory cell string 230 and the control gates adjacent that channel structure 305. Dielectric structure 332 can be configured to facilitate tunneling of charge (e.g., holes or electrons) between charge storage structure 202 and an adjacent control gate (e.g., the control gate closest to charge storage structure 202). Dielectric structure 333 can be configured to block tunneling of charge between charge storage structure 202 and a control gate.

Each of dielectric structures 331, 332, and 333 can include opposite sides (e.g., left and right sides in the X-direction) adjacent (e.g., directly in contact with) elements respective memory cell strings 230 and respective control gates (e.g., control gates 250.1, 251.1, 252.1, 253.1, 250.2, 251.2, 252.2, 253.2, 250.3, 251.3, 252.3, and 253.3) of memory device 200. For example, as shown in FIG. 3A, dielectric structure 332 in memory cell string 230 coupled to data line 271.1 includes a side (e.g., left side in the X-direction) adjacent charge storage structures 202 of memory cell string 230 coupled to data line 271.1 and another side (e.g., right side in the X-direction) adjacent control gates 250.2, 251.2, 252.2, and 253.2. In another example, as shown in FIG. 3A, dielectric structure 331 in memory cell string 230 coupled to data line 272.1 includes a side (e.g., left side in the X-direction) adjacent control gates 250.2, 251.2, 252.2, and 253.2 and another side (e.g., right side in the X-direction) adjacent channel structure 305 of memory cell string 230 coupled to data line 272.1.

Charge storage structures 202 of respective memory cells 210, 211, 212, and 213 of a particular memory cell string 230 can be located (e.g., formed) along the length (in the z-direction) of a respective channel structure 305 of that particular memory cell string 230. As described above, example materials for charge storage structures 202 include a dielectric material (e.g., silicon nitride), polysilicon, metal, or other charge storage materials.

As shown in FIG. 3A, the locations of memory cells 210, 211, 212, and 213 of a particular memory cell string 230 can be at or near the locations of respective charge storage structures 202 of that particular memory cell string 230. Memory cells 210, 211, 212, and 213 of the same memory cell string 230 can be located (e.g., formed) one over another in the Z-direction, which is perpendicular to substrate 399 (e.g., perpendicular to the X-Y plane of substrate 399). As shown in FIG. 3A, the direction from one memory cell to the next (from memory cell 210 to memory cell 211) within the same memory cell string 230 is also the Z-direction.

As shown in FIG. 3A, the control gates associated with signals WL1, WL2, WL3, and WL4 can be located one over another in respective levels (e.g., respective tiers) 310, 311, 312, and 313 in the Z-direction over sources 290 of memory device 200. FIG. 3A shows an example of four levels 310, 311, 312, and 313 associated with four levels of memory device 200 where control gates associated with signals WL1, WL2, WL3, and WL4 are located. However, memory device 200 can include numerous levels (similar to levels 310, 311, 312, and 313). The number of the levels (e.g., tiers) of memory cells can be dependent on (e.g., can be the same as) the levels of the control gates of memory device 200.

As shown in FIG. 3A, the control gates (associated with signals WL1, WL2, WL3, and WL4) of memory device 200 can have respective lengths in the Y-direction, which is a direction perpendicular to a direction (e.g., the Z-direction) from one memory cell to the next memory cell of the same memory cell string 230. As shown in FIG. 3A, each of the control gates can have a width in the X-direction and a thickness in the Z-direction. In each control gate, the dimension (e.g., measure in micrometer unit) of each of the width and the thickness is less than the dimension (e.g., measure in micrometer unit) of the length.

As shown in FIG. 3A, each of the control gates of memory device 200 can be separated (e.g., electrically isolated) from adjacent elements by respective dielectric structures. For example, control gate 252.2 is separated from charge storage structure 202 of memory cell 212 of memory cell string 230 coupled to data line 271.1 by dielectric structure 332 (dielectric structure 332 adjacent charge storage structure 202 of memory cell string 230 coupled to data line 271.1). Control gate 252.2 is also separated from channel structure 305 of memory cell string 230 coupled to data line 272.1 by dielectric structure 331 (dielectric structure 331 adjacent channel structure 305 of memory cell string 230 coupled to data line 272.1)

As shown in FIG. 3A, memory cell strings 230 can be located (e.g., formed) adjacent each other in the X-direction or in the Y-direction. Adjacent memory cell strings 230 in the X-direction are two memory cell strings 230 that are immediately located next to each other in the X-direction. For example, memory cell strings 230 coupled to respective data lines 271.1 and 272.1 (associated with signals BL1₁ and BL1₂, respectively) adjacent memory cell strings 230 in the X-direction.

Adjacent memory cell strings 230 in the Y-direction are two memory cell strings 230 that are immediately located next to each other in the Y-direction. For example, memory cell strings 230 coupled to respective data lines 271.1 and 271.2 are adjacent memory cell strings 230 in the Y-direction.

In FIG. 3A, adjacent channel structures 305 in the X-direction are two channel structures 305 that are located immediately next to each other in the X-direction. Adjacent channel structures 305 in the Y-direction are two channel structures 305 that are located immediately next to each other in the Y-direction.

As shown in FIG. 3A, each group of control gates can be located between adjacent memory cell strings in the X-direction. For example, control gates 250.1, 251.1, 252.1, and 253.1 can be located between memory cell strings 230 coupled to respective data lines 271.1 and 272.1. In another example, control gates 250.2, 251.2, 252.2, and 253.2 can be located between memory cell strings 230 coupled to respective data lines 272.1 and 273.1.

As shown in FIG. 3A, on a particular level (e.g., level 312) of memory device 200, only one control gate (among control gates 250.1, 251.1, 252.1, 253.1, 250.2, 251.2, 252.2, 253.2, 250.3, 251.3, 252.3, and 253.3) is located (e.g., formed) between two respective channel structures 305 of adjacent memory cell strings 230 in the X-direction. For example, on level 312 in FIG. 3A, only control gate 252.2 is located between two channel structures 305 of respective memory cell strings 230 coupled to respective data lines 271.1 and 272.1.

As shown in FIG. 3A, on a particular level (e.g., level 312) of memory device 200, only one charge storage structure 202 of a memory cell is located (e.g., formed) between two channel structures 305 of two respective adjacent memory cell strings 230 in the X-direction. For example, on level 312 in FIG. 3A, only charge storage structure 202 of memory cell 212 (adjacent control gates 252.2) is located between two channel structures 305 of respective memory cell strings coupled to respective data lines associated 271.1 and 272.1.

Thus, as shown in FIG. 3A, on a particular level (e.g., level 312) of memory device 200, there are a control gate (e.g., only control gate 252.2) and a charge storage structure (e.g., charge storage structure 202 of memory cell 212 adjacent control gates 252.2) between two channel structures 305 of adjacent memory cell strings 230 in the X-direction (e.g., channel structures 305 of respective memory cell strings 230 coupled to respective data lines 271.1 and 272.1)

Structuring memory device 200 as shown and described above with reference to FIG. 3A can provide improvements and benefits to memory device 200 in comparison to some conventional memory devices. For example, some conventional memory devices may separate control gates for read and write operations of adjacent memory cells. Using such separate control gates can cause conventional memory devices to have a relatively higher number of control gates. This can lead to lower memory cell density and difficulty in scaling ability.

In memory device 200 as described above, since the same control gate can be used (e.g., can be shared) in read and write operations of different memory cells (e.g., adjacent memory cells), the number of control gates and associated drivers (e.g., word line drivers) can be relatively smaller than that of some conventional memory devices. A smaller number of control gates and associated drivers allows memory device 200 to have a relatively smaller size (e.g., smaller footprint, smaller memory area, or both). This allows memory device 200 to have a higher memory cell density and a higher opportunity for device scaling.

FIG. 3B shows an alternative structure of memory device 200 of FIG. 3A. Differences between memory devices 200 in FIG. 3A and FIG. 3B include structures 202′ in FIG. 3B. As shown in FIG. 3B, memory device 200 can include structures 202′ at the locations of respective select transistors 261D and 260S. As shown in FIG. 3A, memory device 200 is void of (without) structures 202′. In FIG. 3B, the material of structures 202′ can be similar to or the same as the material (e.g., charge storage material) of charge storage structure 202. Thus, structure 202′ can also be called a charge storage structure. However, unlike charge storage structure 202 of a memory cell of memory device 200 in FIG. 3B, structures 202′ are not used to store information (e.g., a bit (or multiple bits) of data). As shown in FIG. 3A, each channel structure 305 of a respective memory cell string 230 is associated with two select transistors 261D (only one is labeled) on respective sides (e.g., left and right sides in the X-direction) and two select transistors 260S (only one is labeled) on respective sides (e.g., left and right sides in the X-direction) of respective memory cell string 230. Structures 202′ can be configured (e.g., to store charge) such that select transistors 261D and 260S on the same side (e.g., right side) of a respective memory cell string 230 can have a relatively high threshold voltage (Vt). This allows memory device 200 to control (e.g., turn on or turn off) select transistors 261D and 260S on only one side (e.g., left side) of a respective memory cell string 230 during an operation (e.g., read or write operation) of memory device 200. Memory device 200 in FIG. 3A and FIG. 3B can include similar or the same improvements and benefits.

FIG. 3C shows another alternative structure of memory device 200 of FIG. 3A. Differences between memory devices 200 in FIG. 3A and FIG. 3C include the material 302 in FIG. 3C. FIG. 3A shows an example memory device 200 where charge storage structures 202 (in the Z-direction) of the same memory cell string 230 are separated from each other by a respective dielectric material (in the Z-direction, not labeled) between two adjacent charge storage structures 202. However, as shown in FIG. 3CB, charge storage structures 202 (in the Z-direction) of the same memory cell string 230 can be part of a continuous structure, which includes a continuous piece of material 302. As shown in FIG. 3C, material 302 can extend continuously in the Z-direction without a dielectric (e.g., without void (e.g., without a discontinuity) in material 302) between two adjacent charge storage structures 202. Examples of material 302 include a dielectric material (e.g., silicon nitride), polysilicon, metal, or other materials that can be structured to store charge (e.g., can trap charge) to store information. Memory device 200 in FIG. 3A and FIG. 3C can include similar or the same improvements and benefits.

The structure of memory device 200 as described above allows memory device 200 to maintain a relatively high speed in write and erase operations and reduce or prevent read disturbance in read operations.

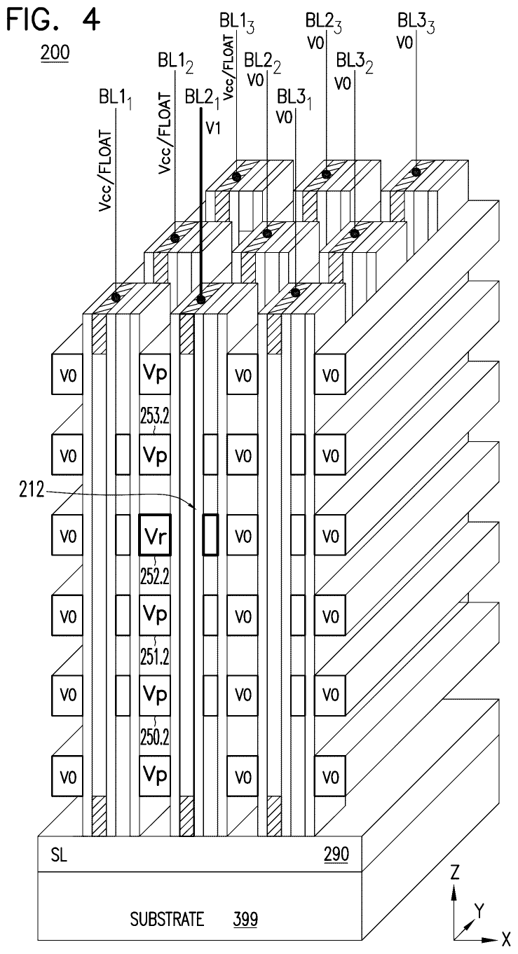

FIG. 4 through FIG. 6B show example voltages applied to circuit elements (e.g., the control gates, the select lines, and the data lines) of memory device 200 during different memory operations (read, write, and erase operations) in memory device 200. The memory device (e.g., memory device 200 and memory device 700 (described below) described herein can include circuitry (not shown) to apply different voltages (described below) to the circuit elements of the memory device during read, write, and erase operations. Such circuitry can include circuitry and elements similar to or the same as those of memory device 100, including control unit 118, row and column access circuitry 108 and 109, sense and buffer circuitry 120, and other circuitry of a memory device, such as the memory device described herein.

FIG. 4 shows example values of signals used during a read operation in memory device 200 of FIG. 3A, according to some embodiments discussed herein. For simplicity, labels for some of the elements of memory device 200 of FIG. 3A are omitted from FIG. 4. In the example of FIG. 4, the selected memory cell is assumed to be memory cell 212 of the memory cell string 230 (labeled in FIG. 3A) coupled to the data line associated with signal BL2₁. The read operation associated with FIG. 4 can read information previously stored (using a write operation) in memory cell 212. The value of information read from memory cell 212 during a read operation can be determined by sensing the value (e.g., voltage or current value) on data line associated signal BL2 during the read operation.

As shown in FIG. 4, the control gates, the select lines, the data lines can be selectively applied with different voltages (e.g., voltages V0, Vcc, V1, Vp, and Vr) or placed in a float (FLOAT) condition. Voltage V0 can have a value of zero volts (e.g., ground potential). Voltage Vcc can be the voltage supply of memory device 200. Voltage V1 can be greater than V0 and less than voltage Vcc. In FIG. 4, “Vcc/FLOAT” on a particular data line indicates that the particular data line can be either applied with voltage Vcc or placed in a float condition (not coupled to a fixed voltage).

Voltage V0 can be applied to control (e.g., turn off) transistors in memory cells or to control (e.g., turn off) select transistors (e.g., drain select transistors or source select transistors). Voltage Vp (e.g., pass voltage) can have a positive value. Voltage Vp can be applied to control (e.g., turn on) transistors in unselected memory cells (e.g., memory cells 210, 211, and 213, not labeled in FIG. 4) of the selected memory cell string, which is memory cell string 230 that includes the selected memory cell (e.g., memory cell 212 in FIG. 4). Voltage Vp can also be applied to control (e.g., turn on) select transistors (e.g., drain select transistors or source select transistors) associated with the selected memory cell string. The turned-on transistors of unselected memory cells and select transistors can operate as pass transistors (e.g., pass gates) to allow conduction of current through the turned-on transistors.

Voltage Vr (e.g., read voltage) can have a positive value. Voltage Vr can be applied to control (e.g., turn on or turn off) the transistor in the selected memory cell (e.g., memory cell 212 in FIG. 4) depending on the value (e.g., binary value) of information previously stored in the selected memory cell.

As shown in FIG. 4, although voltage Vr is applied to control gate 252.2 to read information from memory cell 212, voltage Vr may not disturb information (e.g., charge) in adjacent charge storage structures 202 (to the left of control gate 252.2 in FIG. 4) of memory cells in other memory cell strings (to the left of control gate 252.2 in FIG. 4) because channel structures 305 (labeled in FIG. 3A) of the other memory cell strings can be either applied with voltage Vcc or placed in a float condition. Operating memory device 200 with voltages shown in FIG. 4 can provide improvements and benefits to memory device 200 including properly reading a selected memory cell (or memory cells) and reducing or preventing disturbance (e.g., read disturbance) in unselected memory cells in memory device 200.

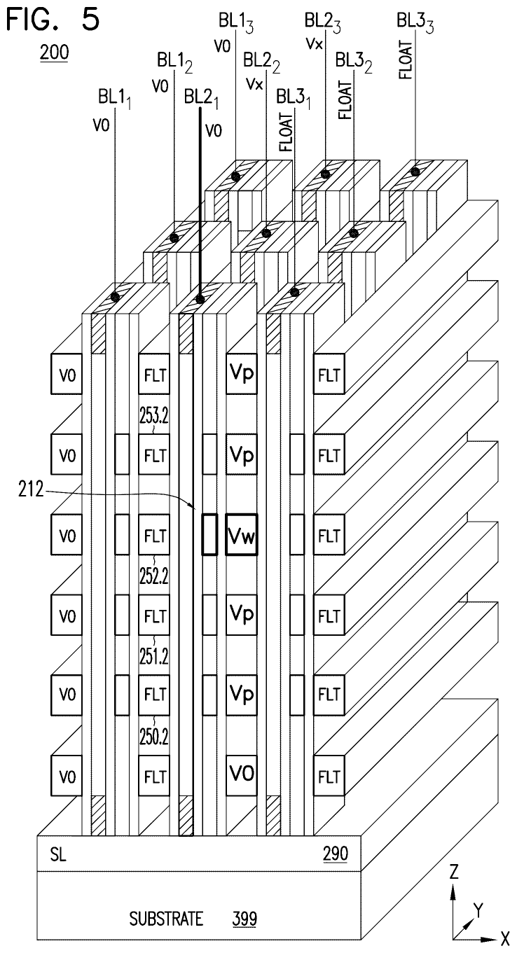

FIG. 5 shows example values of signals used during a write operation in memory device 200 of FIG. 3A, according to some embodiments discussed herein. For simplicity, labels for some of the elements of memory device 200 of FIG. 3A are omitted from FIG. 5. FIG. 5 shows some of the voltages that are similar to or the same as those of FIG. 4. In FIG. 5 “FLT” is short of “FLOAT” condition (described above). For simplicity, the descriptions of the same voltages (e.g., V0 and Vp) or float condition between the figures described herein (e.g., FIG. 4 through FIG. 12B) are not repeated.

In the example of FIG. 5, the selected memory cell is assumed to be memory cell 212 of memory cell string 230 (not labeled) coupled to a data line associated with signal BL2₁. The write operation associated with FIG. 5 can store information in memory cell 212. The value of information to be stored in memory cell 212 can be determined by the value of voltage Vw applied to control gate 252.2. Voltage Vw (e.g., write voltage or programming voltage) can have a value (e.g., 18 volts to 20 volts) to allow information (in the form of charge) to be stored in the selected memory cell (e.g., memory cell 212 in FIG. 5).

In FIG. 5, a voltage Vx (e.g., inhibit voltage or boosted voltage) can be applied to data lines (e.g., data line associated with signal BL2₂ or BL2₃) associated with unselected memory cell strings adjacent the selected memory cell string in the Y-direction. Voltage Vx applied to a particular data line can have a value to prevent memory cells of the memory cell string coupled to that particular data line from being written (e.g., from being programmed). In an example, voltage Vx can have a value similar to or the same as the value of supply voltage (e.g., voltage Vcc) of memory device 200.

In FIG. 5, the data lines associated with signals BL3₁, BL3₂, and BL3₃ can be placed in a float condition (FLOAT) to prevent charge leakage from channel structures 305 (labeled in FIG. 3A) of memory cell strings 230 (labeled in FIG. 3A) coupled to data lines associated with signals BL3₁, BL3₂, and BL3₃.

The control gates adjacent charge storage structures 202 (not labeled) of the memory cell strings coupled to the data lines associated with signals BL3₁, BL3₂, and BL3₃ can be placed in a float condition (FLT) to prevent disturbance of charge in those charge storage structures.

The control gates adjacent charge storage structures 202 (not labeled) of the memory cell strings coupled to data lines associated with signals BL1₁, BL1₂, and BL1₃ can be placed in a float condition (FLT) to facilitate the voltage boosting of data line associated with signal BL2₂ and BL2₃.

Operating memory device 200 with voltages shown in FIG. 5 can provide improvements and benefits to memory device 200 including properly storing information in the selected memory cell and preventing disturbance (e.g., write disturbance) in unselected memory cells in memory device 200.

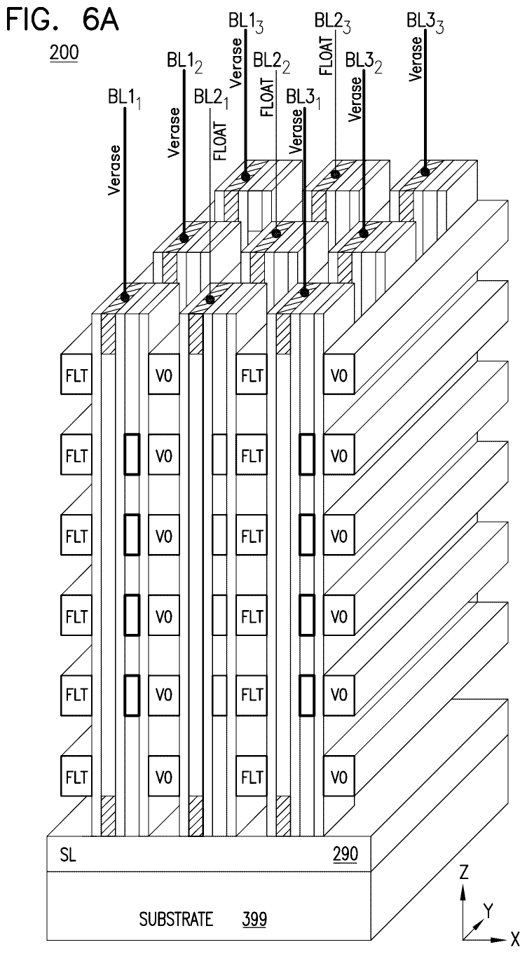

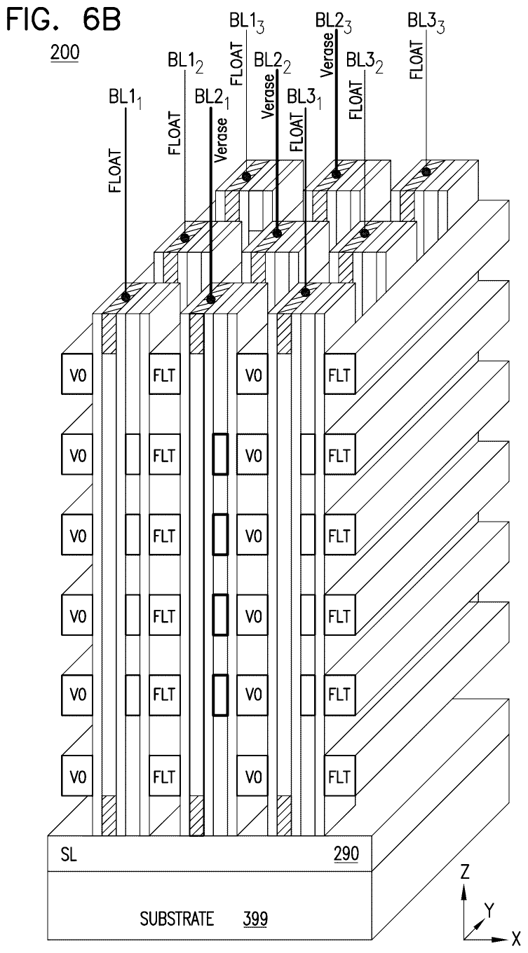

FIG. 6A shows example values of signals used during an erase operation in a portion of memory device 200 of FIG. 3A, according to some embodiments discussed herein. For simplicity, labels for some of the elements of memory device 200 of FIG. 3A are omitted from FIG. 6A. In the example of FIG. 6A, the memory cell strings that are selected to be erased include memory cell strings coupled to data lines having voltage Verase applied thereon. The memory cell strings that not selected to be erased include the memory cell strings coupled to the data lines being placed in a float condition (FLOAT).

In an erase operation of memory device 200, as shown in FIG. 6A, some of the control gates (and select lines) can be applied with voltage V0 and some other control gates (and select lines) can be placed in a float condition (FLT). Voltage Verase (selectively applied to the data lines) can have an appropriate value (e.g., 20 volts to 22 volts) to allow information stored in the selected memory cells to be erased.

As shown in FIG. 6A, in an erase operation of memory device 200, a portion of the memory cell strings (coupled to data lines having voltage Verase) can be selected to be erased and another portion of the memory cell strings (coupled to data lines in a float condition) can be unselected memory cells strings (not selected to be erased). For example, the memory cell strings coupled to data lines associated with signals BL1₁, BL1₂, and BL1₃ and signals BL3₁, BL3₂, and BL3₃ can be selected to be erased. The memory cell strings coupled to data lines associated with signals BL2₁, BL2₂, and BL2₃ can be unselected (not selected to be erased) memory cell strings. In a subsequent erase operation (e.g., as shown in FIG. 6B), memory device 200 can switch the selection of selected memory cell strings and unselected memory cell strings, so that adjacent memory cell strings (in the X-direction) can be erased in different erase operations.

FIG. 6B shows example values of some signals used during an erase operation in another portion of memory device 200 of FIG. 3A, according to some embodiments discussed herein. The erase operation associated with FIG. 6B can be performed on unselected memory cell strings in the erase operation associated with FIG. 6A. Selected memory cell strings in FIG. 6A can become unselected memory cell strings (not selected to be erased) in the erase operation associated with FIG. 6B. For the erase operation associated with FIG. 6B, voltage Verase and float condition applied to respective data lines in FIG. 6A can be swapped (exchanged). Similarly, for the erase operation associated with FIG. 6B, voltage V0 and float condition applied to respective control lines in FIG. 6A can be swapped (exchanged). Operating an erase operation in memory device 200 as described with reference to FIG. 6A and FIG. 6B can provide improvements and benefits to memory device 200 including reducing or preventing damage (e.g., gate oxide damage or gate oxide breakdown) in the structure of memory device 200.

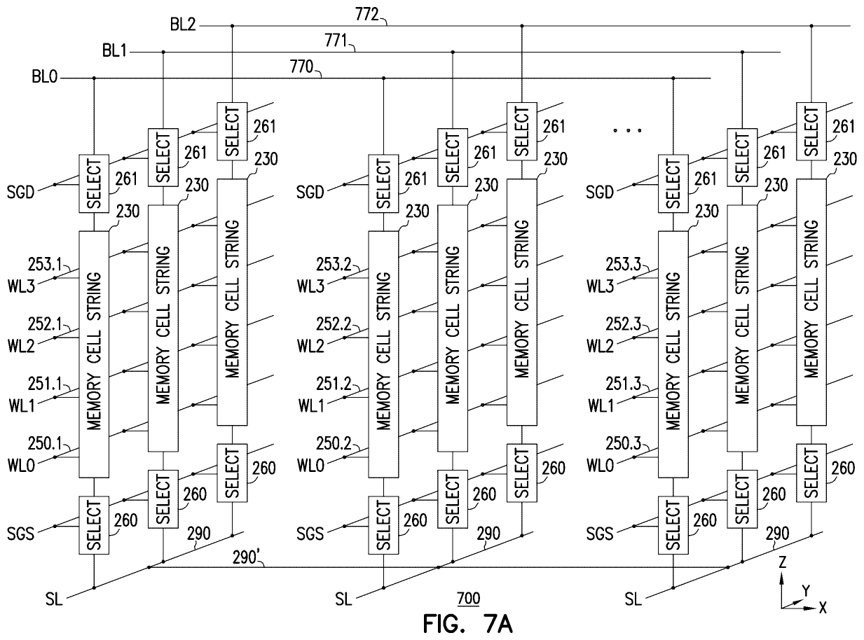

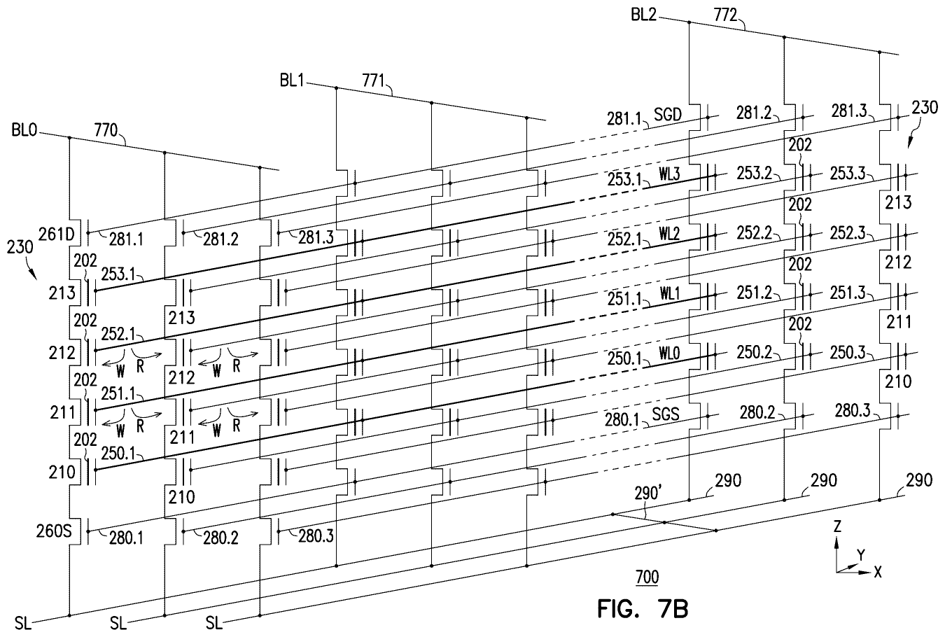

FIG. 3A, FIG. 3B, and FIG. 3C show an example where memory device 200 includes separate data lines for the memory cell strings. However, some memory cell strings (e.g., adjacent memory cell strings in the X-direction) can share respective data lines, as described below with reference to FIG. 7A through FIG. 12B.

FIG. 7A and FIG. 7B show a structure of a portion of a memory device 700, according to some embodiments described herein. FIG. 7B shows details of memory device 700 of FIG. 7A. Memory device 700 can include elements that are similar to or the same as those of memory device 200 described above. For simplicity, a detailed description of similar or same elements is not repeated.

Differences between memory devices 200 and 700 include data lines 770, 771, and 772 of memory device 700 that can be shared between memory cell strings 230 (in the X-direction) associated with different groups of control gates. For example, as shown in FIG. 7A and FIG. 7B, each of data lines 770, 771, and 772 can be shared by respective memory cell strings 230 that are adjacent each other in the X-direction.

FIG. 7B shows details of memory device 700 of FIG. 7A that include elements similar to or the same as memory device 200 in FIG. 2B, except for data lines 770, 771, and 772 in FIG. 7B. Thus, for simplicity, a detailed description of FIG. 7B is omitted herein.

FIG. 8A shows of a structure of a portion of memory device 700 of FIG. 7A and FIG. 7B, according to some embodiments described herein. The structure of memory device 700 in FIG. 8A can include elements that are similar to or the same as those of memory device 200 shown in FIG. 3A. For simplicity, a detailed description of similar or the same elements is not repeated. Differences in the structures between memory devices 200 and 700 include data lines 770, 771, and 772 of memory device 700 in FIG. 8A.

FIG. 8B shows an alternative structure of memory device 700 of FIG. 8A. Differences between memory devices 700 in FIG. 8A and FIG. 8B include the structures 202′ in FIG. 8B. The structure of memory device 700 in FIG. 8B is similar to the structure of memory device 200 in FIG. 3B, except for shared data lines 770, 771, and 772 in FIG. 8B. Thus, for simplicity, a detailed description of FIG. 8B is omitted herein. Memory device 700 in FIG. 8A and FIG. 8B can include similar or the same improvements and benefits.

FIG. 8C shows another alternative structure of memory device 700 of FIG. 8A. Differences between memory devices 700 in FIG. 8A and FIG. 8C include material 302 in FIG. 8C. The structure of memory device 700 in FIG. 8C is similar to the structure of memory device 200 in FIG. 3C, except for shared data lines 770, 771, and 772 in FIG. 8C. Thus, for simplicity, a detailed description of FIG. 8C is omitted herein. Memory device 700 in FIG. 8A and FIG. 8C can include similar or the same improvements and benefits.

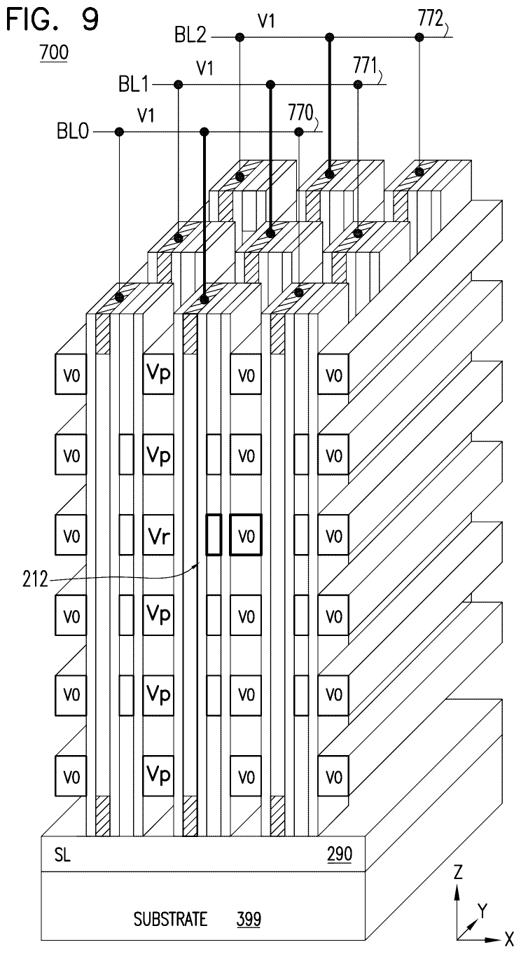

FIG. 9 through FIG. 12B show example voltages applied to circuit elements (e.g., the control gates, the select lines, and the data lines) of memory device 700 during different memory operations (read, write, and erase operations) in memory device 700. The voltages and float condition (FLOAT or FLT) in FIG. 9 through FIG. 12B are similar to or the same as those in FIG. 4 through FIG. 6B. Thus, detailed descriptions of similar or the same elements and similar or the same operations are not repeated.

FIG. 9 shows example values of signals used during a read operation in memory device 200 of FIG. 8A, according to some embodiments discussed herein. In FIG. 9, the read operation can read information from memory cells 212 (only one memory cell 212 is labeled in FIG. 9) of the memory cell strings coupled located between the group of control gates 250.2, 251.2, 252.2, and 253.2 (labeled in FIG. 8A) and the group of control gates 250.3, 251.3, 252.3, and 253.3 (labeled in FIG. 8A).

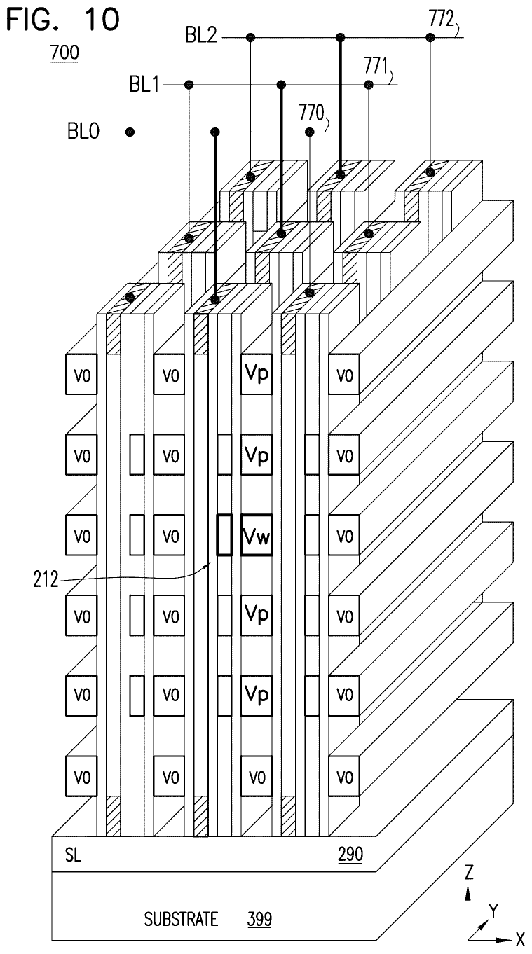

FIG. 10 shows example values of signals used during a write operation in memory device 200 of FIG. 8A, according to some embodiments discussed herein. In FIG. 10, the write operation can store information in memory cells 212 (only one memory cell 212 is labeled in FIG. 9) of the memory cell strings located between the group of control gates 250.2, 251.2, 252.2, and 253.2 (labeled in FIG. 8A) and the group of control gates 250.3, 251.3, 252.3, and 253.3 (labeled in FIG. 8A).

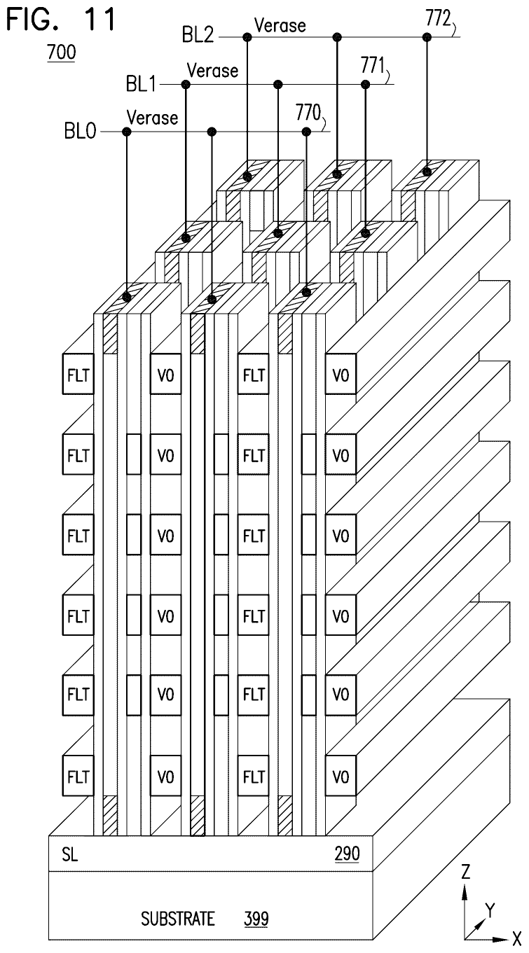

FIG. 11 shows example values of signals used during an erase operation in a portion of memory device 200 of FIG. 8A, according to some embodiments discussed herein. In FIG. 11, the erase operation can erase memory cells (e.g., memory cells 210, 211, 212, and 213, labeled in FIG. 8A) from the memory cell strings (e.g., nine memory cell strings) coupled to data lines 770, 771, and 772.

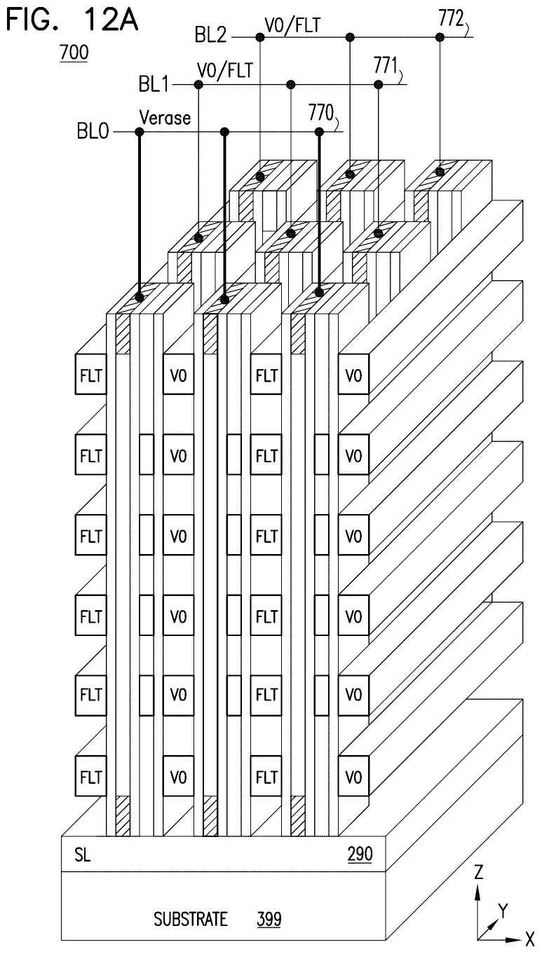

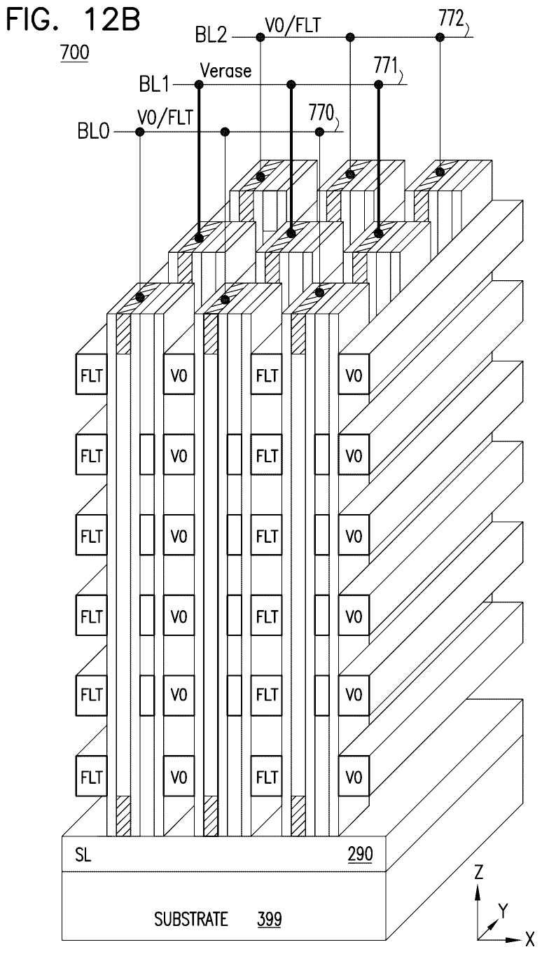

FIG. 12A shows example values of signals used during another erase operation in a portion of memory device 200 of FIG. 8A, according to some embodiments discussed herein. In FIG. 12A, a portion of the memory cell strings (coupled to data lines having voltage Verase) can be selected to be erased and another portion of the memory cell strings (coupled to data lines in a float condition) can be unselected memory cells strings (not selected to be erased). For example, the memory cell strings coupled to data line 770 can be selected to be erased. The memory cell strings coupled to data lines 771 and 772 can be unselected (not selected to be erased) memory cell strings. In a subsequent erase operation (e.g., as shown in FIG. 12B), memory device 700 can switch the selection of selected memory cell strings and unselected memory cell strings, so that adjacent memory cell strings (in the Y-direction) can be erased in different erase operations. These alternating erase operations can reduce or prevent damage (e.g., gate oxide damage or gate oxide breakdown) in the structure of memory device 700.

FIG. 12B shows example values of some signals used during an erase operation in another portion of memory device 700 of FIG. 3A, according to some embodiments discussed herein. The erase operation associated with FIG. 12B can be performed on unselected memory cell strings in the erase operation associated with FIG. 12A. Selected memory cell strings in FIG. 12A can become unselected memory cell strings (not selected to be erased) in the erase operation associated with FIG. 12B. For example, unlike FIG. 12A, the memory cell strings coupled to data line 771 can be selected memory cell strings to be erased. The memory cell strings coupled to data lines 770 and 772 can be unselected (not selected to be erased) memory cell strings. For the erase operation associated with FIG. 12B, voltage Verase and float condition applied to respective data lines in FIG. 12A can be swapped (exchanged). Similarly, for the erase operation associated with FIG. 12B, voltage V0 and float condition applied to respective control lines in FIG. 12A can be swapped (exchanged).

Memory device 700 described above with reference to FIG. 7A through FIG. 12B can include similar or the same improvements and benefits as those of memory device 200 described above with reference to FIG. 2A through FIG. 6B.

The illustrations of apparatuses (e.g., memory devices 100, 200, and 700) and methods (e.g., method of operating memory devices 100, 200 and 700) are intended to provide a general understanding of the structure of various embodiments and are not intended to provide a complete description of all the elements and features of apparatuses that might make use of the structures described herein. An apparatus herein refers to, for example, either a device (e.g., any of memory devices 100, 200, and 700) or a system (e.g., a computer, a cellular phone, or other electronic systems) that includes a device such as any of memory devices 100, 200, and 700.

Any of the components described above with reference to FIG. 1 through FIG. 12B can be implemented in a number of ways, including simulation via software. Thus, apparatuses, e.g., memory devices 100, 200, and 700, or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

Memory devices 100, 200, and 700 may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 12B include apparatuses and methods of forming the apparatuses. One of the apparatuses includes a memory device, which includes a first memory cell string, a second memory cell string adjacent the first memory cell string, and a control gate. The first memory string includes a first channel structure, a first charge storage structure, and a first dielectric structure between the first channel structure and the first charge storage structure. The second memory cell string includes a second channel structure, a second charge storage structure, and a second dielectric structure between the second channel structure and the second charge storage structure. The control gate is separated from the first charge storage structure by a third dielectric structure and separated from the second channel structure by a fourth dielectric structure. The control gate and the first charge storage structure are between the first channel structure and the second channel structure. Other embodiments including additional apparatuses and methods are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the terms “first”, “second”, and “third,” etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
a first memory cell string including a first channel structure, a first charge storage structure, and a first dielectric structure between the first channel structure and the first charge storage structure;
a second memory cell string adjacent the first memory cell string, the second memory cell string including a second channel structure, a second charge storage structure, and a second dielectric structure between the second channel structure and the second charge storage structure; and
a control gate separated from the first charge storage structure by a third dielectric structure and separated from the second channel structure by a fourth dielectric structure, wherein the control gate and the first charge storage structure are between the first channel structure and the second channel structure.

2. The apparatus of claim 1, wherein the control gate includes a length in a direction perpendicular to a direction between first and second memory cell strings.

3. The apparatus of claim 1, further comprising:
a first data line associated with the first memory cell string; and
a second data line associated with the second memory cell string.

4. The apparatus of claim 1, further comprising a data line associated with the first and second memory cell strings.

5. The apparatus of claim 1, wherein the first memory cell string includes a first additional charge storage structure; and
wherein the first charge storage structure is configured to store information in a first memory cell of the first memory cell string; and
the first additional charge storage structure is configured to store information in a second memory cell of the first memory cell string, and the charge storage structure and additional charge storage structure are separated from each other by a dielectric material.

6. The apparatus of claim 1, wherein the first memory cell string includes a first additional charge storage structure; and
wherein the first charge storage structure is configured to store information in a first memory cell of the first memory cell string; and
the first additional charge storage structure is configured to store information in a second memory cell of the first memory cell string, and the charge storage structure and additional charge storage structure are part of a continuous piece of material.

7. The apparatus of claim 1, wherein the charge storage structure includes a polysilicon material.

8. The apparatus of claim 1, wherein the charge storage structure includes a dielectric material.

9. The apparatus of claim 1, wherein the charge storage structure includes a metal material.

10. An apparatus comprising:
a conductive region;
a first memory cell string including a first channel structure coupled to the conductive region, and first charge storage structures along the first channel structure and separated from the first channel structure by a first dielectric structure;
a second memory cell string including a second channel structure coupled to the conductive region, and second charge storage structures along the second channel structure and separated from the first channel structure by a second dielectric structure;
control gates associated with the first memory cells and the second memory cell, the control gates located one over another in the conductive region and between the first and second memory strings;
a third dielectric structure including a first side adjacent the first charge storage structures and a second side adjacent the control gates; and
a fourth dielectric structure including a first side adjacent the control gates and a second side adjacent the second channel structure.

11. The apparatus of claim 10, further comprising a substrate, wherein:
the conductive region is located over the substrate; and
the first and second memory cell string are located over the conductive region.

12. The apparatus of claim 10, wherein each of the control gates includes a length in a direction perpendicular to a direction between first and second channel structures.

13. The apparatus of claim 10, wherein:
the first dielectric structure is configured to facilitate tunneling of charge between the first charge storage structures and the first channel structure; and
the second dielectric structure is configured to facilitate tunneling of charge between the second charge storage structures and the second channel structure.

14. An apparatus comprising:
a first memory cell included in a first memory cell string;
a second memory cell included in a second memory cell string;
a third memory cell included in a third memory cell string;
a first control gate to select the first memory cell in a first write operation and to select the second memory cell in a first read operation;
a second control gate to select the second memory cell in a second write operation and to select the third memory cell in a second read operation.

15. The apparatus of claim 14, wherein the first and second control gates are further configured to select the first, second, and third memory cells in an erase operation.

16. The apparatus of claim 14, further comprising:
a first data line associated with the first memory cell string;
a second data line associated with the second memory cell string; and
a third data line associated with the third memory cell string.

17. The apparatus of claim 16, further comprising circuitry to apply different voltages to the first, second, and third data line during the first read operation.

18. The apparatus of claim 16, further comprising circuitry to place the third data line in a float condition during the first write operation.

19. The apparatus of claim 14, further comprising a data line associated with the first, second, and third memory cell strings.

20. The apparatus of claim 19, further comprising circuitry to place the data line in one of a float condition and ground potential during an erase operation.
